(19) United States
(12) Patent Application Publication
(10) Pub. No.: US 2007/0218629 A1
(43) Pub. Date: Sep. 20, 2007

(54) Method of fabricating an integrated memory device

(75) Inventors: Matthias Kronke, Dresden (DE); Detlef Weber, Hermsdorf (DE)

Correspondence Address: MORRISON & FOERSTER LLP, 1650 TYSONS BOULEVARD, SUITE 400, MCLEAN, VA, 22102, US

(73) Assignee: INFINEON TECHNOLOGIES AG, Munchen (DE)

(21) Appl. No.: 11/375,590

(22) Filed: Mar. 15, 2006

(51) Int. Cl. H01L 21/336

(52) U.S. Cl. 438/257

(57) ABSTRACT

Method of fabricating an integrated memory device including the steps of providing a semiconductor substrate, including an array region and a support region; providing GC-lines in said array region and in said support region, wherein the GC-lines in said support region have a first height; providing in the array region bit line contacts projecting above said GC-lines, wherein said bit line contacts have a second height being higher than said first height; providing a first isolation layer, the maximum height of said GC-lines in said support region including the coverage of said first isolation layer being lower than said second height; providing a second isolation layer on said first isolation layer; and polishing said first isolation layer and said second isolation layer, such that a planar surface of the integrated memory device is provided and such that said bit line contacts are exposed.

### BACKGROUND OF THE INVENTION

1. Field of the Invention

The present invention relates to a method of fabricating an integrated memory device on a semiconductor substrate.

2. Description of the Related Art

The semiconductor industry has developed and established sophisticated processes and methods of manufacturing highly integrated electronic circuits, such as microprocessors or electronic memory devices. In the latter case of electronic memory devices, the integration of as many memory cells as possible on a chip is subject to intense industrial and scientific research. The memory cells hold one unit of information, normally referred to as a “bit”, such a “bit” representing one of two possible states “0” and “1”.

Many types of electronic memory devices have evolved over recent years, each type having its advantages and being especially developed for their respective purposes. For example, the dynamic random access memory (DRAM) has been optimized in respect to speed and memory capacity—compromising for volatility. While achieving said advantages, a DRAM does not hold its memory content for a considerable time span, and must be therefore constantly refreshed. Various methods and improvements are employed by modern manufacturing processes in order to increase the number of memory cells being integrated into an electronic memory device, e.g. a DRAM.

A DRAM memory cell usually comprises a storage capacitor and a selection transistor. Such cells are arranged in a regular manner in a so-called array field and are electrically contacted by gate lines (GC-lines) and—perpendicular thereto—bit lines. An improved fabrication of smaller memory cells basically translates to reducing the width and the space of GC-lines of the transistors. With decreasing the space between GC-lines however, it becomes more and more difficult to fill the spaces between facing GC-lines with isolating material.

For a usual process flow, boron-phosphate-silicate-glass (BPSG) is deposited as an isolation material. For this material the gap fill properties can be improved by increasing the boron and phosphate dopant concentration. The disadvantage of increasing dopant concentration is that the material becomes softer. Subsequent to deposition, the material has to be planarized, in order to provide a planar surface for following contacts and metal layers. For such a planarization normally chemical mechanical polishing (CMP) processes are used. However, the combination of soft materials with CMP processes may give rise to large dishing, i.e. an unevenness of the resulting polished surface. Furthermore, an increased defectivity may result, which is a figure of how many defects an otherwise crystalline structure comprises.

This effect is especially pronounced in the case of memory devices, because the array region behaves different regarding polishing processes in comparison to the support region, being arranged alongside the array region. In said array region the memory cells are arranged in a regular manner, whereas in said support region supportive electronic entities are arranged in an irregular manner.

For example, one method of fabricating contacts in the array region is the usage of dummy contacts, in which contacts of the memory cell in the array region are formed by means of a sacrificial layer process. After the processing of these dummy contacts, the said BPSG layer is deposited and planarized by means of a CMP process in a way, that the dummy contacts serve as a polish stop layer for the CMP. In contrast to the array region, no stop layer is present in the support region and thus different dishing behavior in the array region and in the support region is likely.

In order to increase the number of memory cells on a device, spacing between GC-lines has to be decreased and the isolation layers, e. g. made from BPSG, become more and more difficult to polish without the disadvantageous occurrence of dishing. Polishing, however, is an indispensable part of established fabrication methods, and therefore there is a need for an improved fabrication process.

### SUMMARY OF THE INVENTION

Taking the deficits of prior art, it is an object of the present invention to provide an improved method of fabricating an integrated device.

This object and other objects are met by the present invention.

According to a first aspect of the present invention, a method of fabricating an integrated memory device is provided, which includes the steps as described in the following:

In an initial step, a semiconductor substrate, including an array region with memory cells and a support region with support electronic devices, is provided. The support region is arranged alongside the array region. The memory cells store the actual memory information content and may comprise a storage capacitor, which can be charged or uncharged, hence representing two distinct information states. The support region and its support electronic devices provide wiring and logic for efficiently writing and reading information into or from the memory cells in the array region.

In a next step, GC-lines are provided on the semiconductor substrate in the array region and in the support region. The GC-lines in the support region have a first height, which is defined as the vertical distance between the top surface of the semiconductor substrate and the top of the GC-lines in the support region.

In a next step, bit line contacts are provided on the semiconductor substrate in the array region. The bit line contacts project above the GC-lines and have a second height, which is defined as the vertical distance between the top surface of the semiconductor substrate and the top of the bit line contacts. This second height is higher than the first height, which implies that the bit line contacts are also projecting above the GC-lines in the support region.

In a next step, a first isolation layer on the semiconductor substrate is provided. This first isolation layer covers the GC-lines and the bit line contacts. The maximum height of the GC-lines in the support region, including the coverage of the first isolation layer is lower than the second height, implying that the bit line contacts are also projecting above the GC-lines in the support region including the coverage of the first isolation layer.

In a next step, a second isolation layer is provided on the first isolation layer.

In a concluding step, both the first isolation layer and the second isolation layer are polished, such that a planar surface of the integrated memory device is provided and such that the bit line contacts are exposed. Therefore, the polishing is conducted such that the entire integrated memory device, including all hitherto said elements, is covered by either only the first isolation layer or by both the first isolation layer and the second isolation layer, except for the bit line contacts.

Once bit line contacts are exposed by means of said polishing, electric contact may be established to said bit line contacts. The inventive method provides an integrated memory device in a preliminary state for further fabrication with a planar surface and reduced dishing. The inventive two-layer configuration of the isolation and planarization entity of the integrated memory device, comprising the first isolation layer and the second isolation layer, can be polished such that no or reduced dishing occurs in the support region: This is ensured by the inventive provision of GC-lines in the support region, bit line contacts in the array region, a first isolation layer, and a second isolation layer, with respective heights which have been carefully adjusted to each other.

The combination of said contacts and layers, with their respective heights according to this aspect of the present invention, allows for a polishing of the first isolation layer and the second isolation layer to reach and expose the bit line contacts in the array region, while the GC-lines in the support region are still covered by both the first isolation layer and the second isolation layer. Hence, the polishing, which is conducted by means of a single polishing process step applying to the entire semiconductor substrate, does not reach or expose the underlying first isolation layer in the support region. This first isolation layer remains entirely covered by the second isolation layer in the support region. An exposure of the first isolation layer there would disadvantageously open a region that is affected by the polishing process with a different abrasion rate. The resulting inhomogeneous abrasion rate would give rise to indentations in the device surface—this being commonly referred to as dishing. Dishing may strongly affect, exacerbate, or even render impossible subsequent processing steps.

According to a second aspect of the present invention a further method of fabricating an integrated memory device is provided:

In an initial step, a semiconductor substrate including memory cells in an array region and support electronic devices in a support region is provided. The support region is arranged alongside the array region.

In a next step, GC-lines of the memory cells are provided on the semiconductor substrate in the array region and GC-lines of the support electronic devices are provided on the semiconductor substrate in the support region.

In a next step, a first dielectric layer is provided on the semiconductor substrate covering the GC-lines. The GC-lines in the support region including the coverage by the first dielectric layer have a GC-line height.

In a next step, a sacrificial layer on the semiconductor substrate is provided in the array region and the support region. The sacrificial layer covers the GC-lines and the first dielectric layer. Further, the sacrificial layer has a minimum height in a region between GC-lines in the array region, this minimum height being higher than the height of the GC-lines in the support region including the coverage by the first dielectric layer. Hence, the sacrificial layer projects above the GC-lines in the support region including the coverage of the first isolation layer.

In a next step, material plugs are provided on the sacrificial layer between GC-lines in the array region. The horizontal extent of the material plugs may be such that parts of the material plugs are arranged above the GC-lines. The material plugs serve as an etching mask for subsequent anisotropic etching.

In the subsequent anisotropic etching step, the sacrificial layer is etched perpendicularly to the semiconductor substrate top surface, and the sacrificial layer is removed in all regions not being covered by the material plugs. The material plugs themselves and the sacrificial layer underneath the material plugs remain, since anisotropic etching predominantly etches vertically to the semiconductor substrate top surface. Subsequently, the material plugs are removed.

In a next step, a second dielectric layer on the semiconductor substrate is provided. The second dielectric layer covers the remainders of the sacrificial layer and the GC-lines.

In a next step, a first isolation layer is provided on the second dielectric layer. The maximum height of the GC-lines in the support region including the coverage of the first and the second dielectric layer and the first isolation layer is lower than the height of the remainders of the sacrificial layer. Hence, the remainders project above the GC-lines in the support region including the coverage by the first and the second dielectric layer and the first isolation layer. Subsequently, a second isolation layer is provided on the first isolation layer.

In a next step, the first isolation layer and the second isolation layer are polished such that a planar surface of the integrated memory device in the respective stage during fabrication is provided and such that the remainders of the sacrificial layer are exposed. Polishing, therefore, is conducted at least as long as the remainders of the sacrificial layer are uncovered from the second isolation layer and the first isolation layer.

In a next step, the remainders of the sacrificial layer and the first dielectric layer underneath the remainders are removed, leaving holes in the first isolation layer and between facing GC-lines in the array region down to the semiconductor substrate top surface, hence exposing said semiconductor substrate.

In a concluding step of the inventive method, bit line contacts are provided by means of filling the holes with a conductive material.

The inventive method, according to the second aspect of the present invention, allows for a fabrication of bit line contacts with a reduced size by means of a sacrificial layer process—hence allowing for a substantial increase of the integrated memory device performance—while reducing or even avoiding dishing in the support region of the semiconductor substrate. The latter is achieved by means of a coverage of the GC-lines in the support region with the first isolation layer and the second isolation layer. Since the remainders of the sacrificial layer project above the GC-lines in the support region including the coverage of the first isolation layer, polishing may be stopped once the remainders are exposed and hence leaving behind both the first isolation layer and the second isolation layer above the GC-lines in the support region. Since polishing-remains within a homogeneous material in the support region—without a locally varying abrasion rate—dishing is suppressed. The inventive method hence provides the integrated memory device in an advantageous interstitial state for further manufacturing.

According to an embodiment of the present invention, the first isolation layer and the second isolation layer are polished such that the GC-lines in the support region remain covered by both the first isolation layer and the second isolation layer. This may be achieved by a height of the bit line contacts which project above the GC-lines in the support region being covered by the first isolation layer. Exposing the bit line contacts in a subsequent stage therefore requires a polishing of the first isolation layer and the second isolation layer to a height just above the GC-lines in the support region including the coverage by the first and the second dielectric layer and the first isolation layer. Polishing may then be stopped, while still being in the second isolation layer.

Preferably, the polishing of the first isolation layer and the second isolation layer may be conducted by means of chemical mechanical polishing (CMP). CMP is an established and very reproducible polishing technique being already a part of many modern manufacturing processes for highly integrated devices, so not requiring any alterations of existent manufacturing processes.

According to another embodiment of the present invention the step of providing the first isolation layer comprises a step of depositing a material of the first isolation layer and a step of annealing the material of the first isolation layer. Since the first isolation layer is provided on top of a semiconductor substrate that already possesses distinct features, comprehensive coverage of the semiconductor substrate and filling of interspaces between surface features, such as the GC-lines, must be ensured. Two-step provision of the first isolation layer allows for an initial deposition of a material which may condense almost arbitrarily on the substrate, since the material is then subsequently annealed and molten, consequently closing gaps and voids. Furthermore, a continuous coverage by the first isolation layer, including all projecting features, is provided.

According to a next embodiment of the present invention the first isolation layer may comprise boron phosphate silicate glass (BPSG). This material may be deposited and annealed advantageously by means of established and reproducible process techniques. Preferably, the BPSG may comprise boron in a concentration ranging from 0% to 6%, and the BPSG may comprise phosphorous in a concentration ranging between 2% and 6%. BPSG with a 0% boron concentration is also referred to as phosphate silicate glass (PSG).

Furthermore, the first isolation layer may be deposited with a first layer thickness, such that this thickness is equal to or greater than half the spacing of the GC-lines in the array region. In this way, it is ensured that the amount of material that later forms the first isolation layer is sufficient for filling interspaces between neighboring GC-lines in the array region. Preferably, this first layer thickness may range from 80 to 180 nm. Additionally, the first isolation layer may be annealed such to remove voids in the deposited material of the first isolation layer and hence provides a continuous and comprehensive coverage of the integrated memory device in this stage of fabrication. The annealing may furthermore reflow the first isolation layer and therewith provide a smoothening of the surface, which allows for a void-free deposition of a subsequent layer, such as the second isolation layer.

According to a next embodiment of the present invention the second isolation layer may comprise silica. It may also comprise undoped silica glass. These materials provide advantageous physical properties for coverage, planarization, and passivation of the device. Said materials may be provided by means of chemical vapor deposition (CVD), which is an established and very reproducible deposition technique. Furthermore, the reactants during CVD may comprise tetraethoxysilane (TEOS) and ozone (O₃). The ozone concentration during CVD may range from 15% to 20%. The second isolation layer may be provided also by means of plasma enhanced chemical vapor deposition (PE-CVD). During this PE-CVD deposition reactants may again comprise TEOS.

According to a next embodiment of the present invention the second isolation layer is provided with a second layer thickness, such that a minimum height of the GC-lines in the support region, including the coverage by the first isolation layer and the coverage by the second isolation layer, is equal to or greater than the second height. In this way, it is ensured that polishing may expose the bit line contacts in the array region, while features in the support region, such as the GC-lines, are still covered by both the first isolation layer and the second isolation layer. The second layer thickness may preferably range from 300 nm to 1000 nm.

According to a next embodiment of the present invention the first dielectric layer comprises silica and the second dielectric layer comprises silicon nitride. Said dielectric materials may be provided by means of established and well reproducible manufacturing techniques, and simultaneously provide advantageous physical properties as applied in an integrated memory device.

According to a next embodiment of the present invention the sacrificial layer comprises silicon, which may be in a polycrystalline state. Since the sacrificial layer is removed in order to form holes in the first isolation layer, there is need for an isotropic selective etching technique that provides sufficient selectivity in order to remove the sacrificial layer only. Silicon may be selectively removed by means of established and well understood etching agents, providing a sufficient and satisfying selectivity.

According to yet another embodiment of the present invention the conductive material comprises a metal, preferably comprising tungsten. Furthermore, the conductive material may comprise a liner layer which may be arranged at the bottom and on a sidewall of the holes, which are filled by the conductive material. In this way, conductive material, such as tungsten, other metals or other conductive compounds, may be hindered to diffuse into functionalized parts of the integrated memory device, causing substantial damage to electronic entities, such as transistors. Said electronic entities are an integral and vital part of integrated memory devices.

### BRIEF DESCRIPTION OF THE DRAWINGS

These and other objects and features of the present invention will become clear from the following description, taken in conjunction with the accompanying drawings in which:

FIGS. 1A through 1H show a schematic view of the integrated memory device during fabrication in various process stages, according to a first embodiment of the present invention;

FIGS. 2A through 2C show a schematic view of the integrated memory device during fabrication in various process stages, according to a second embodiment of the present invention; and

FIGS. 3A through 3I show a schematic view of the integrated memory device during fabrication in various process stages, according to a third embodiment of the present invention.

### DESCRIPTION OF THE PREFERRED EMBODIMENTS

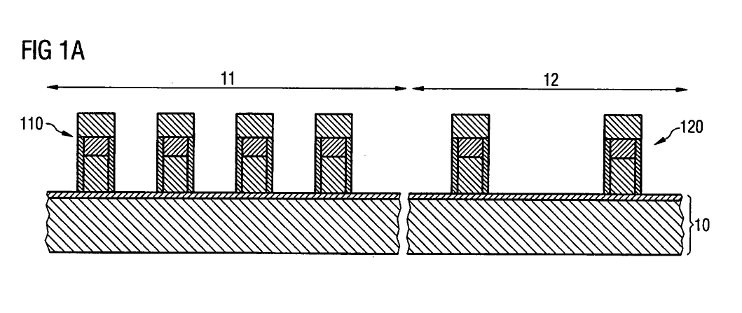

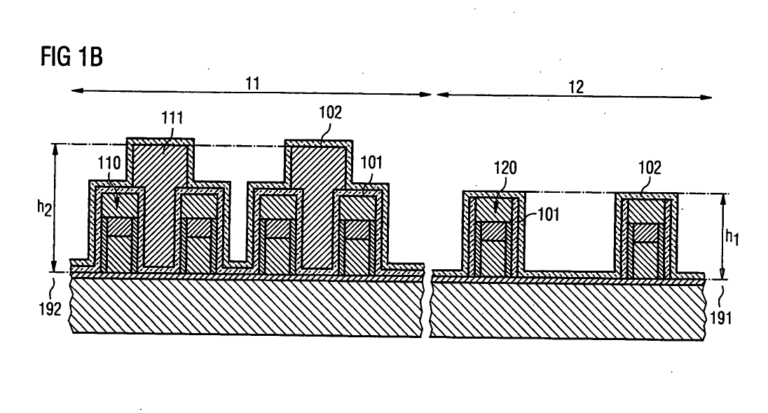

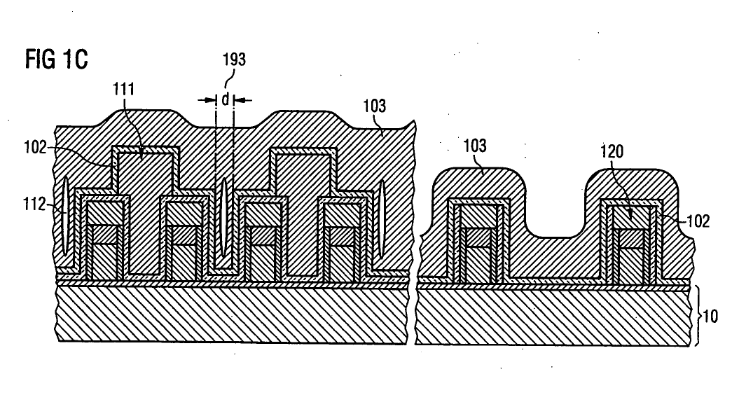

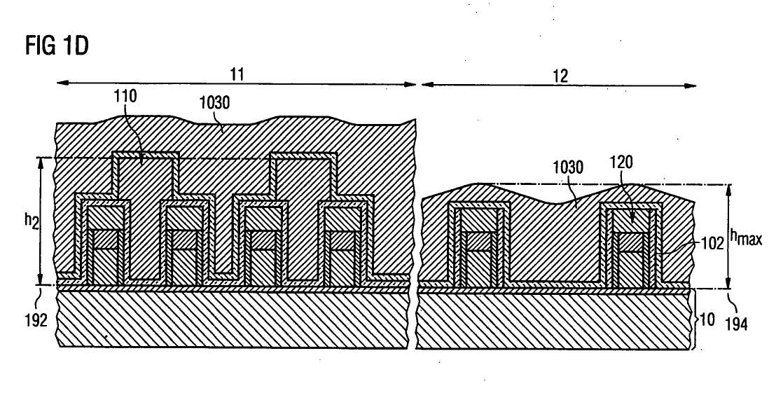

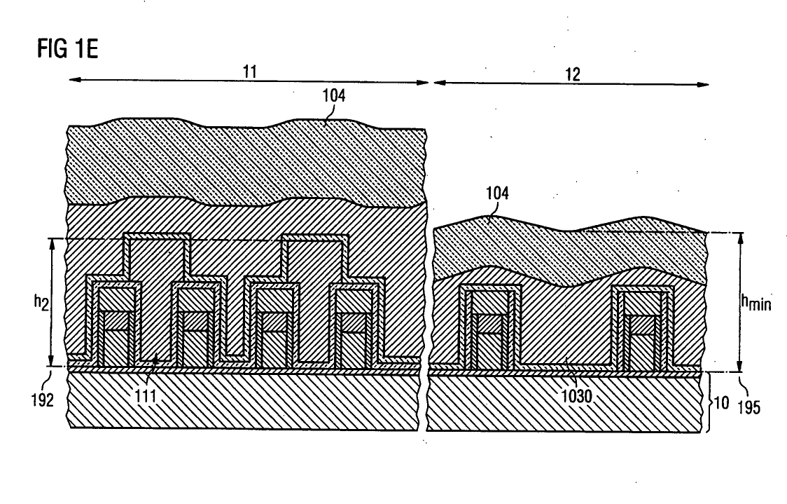

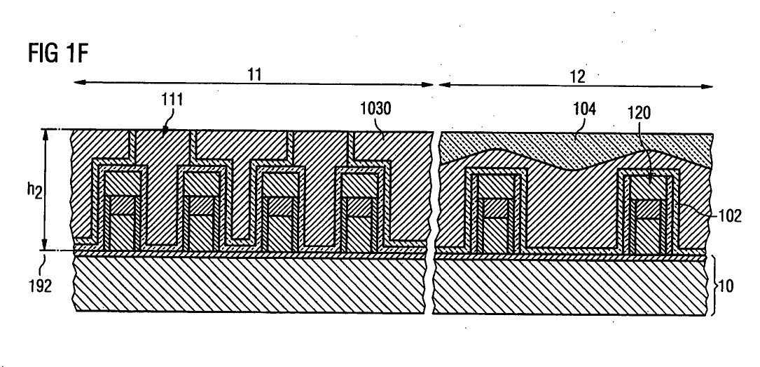

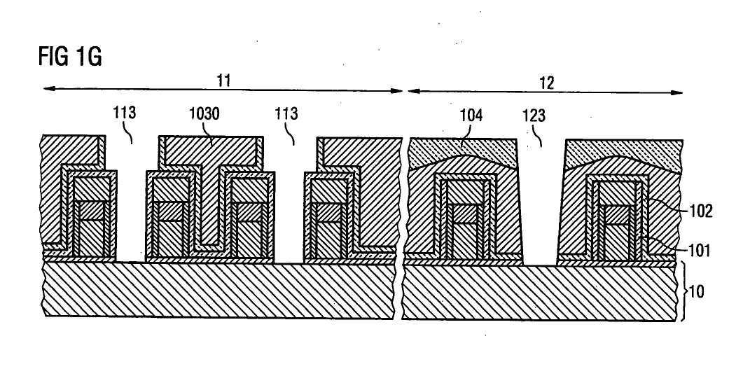

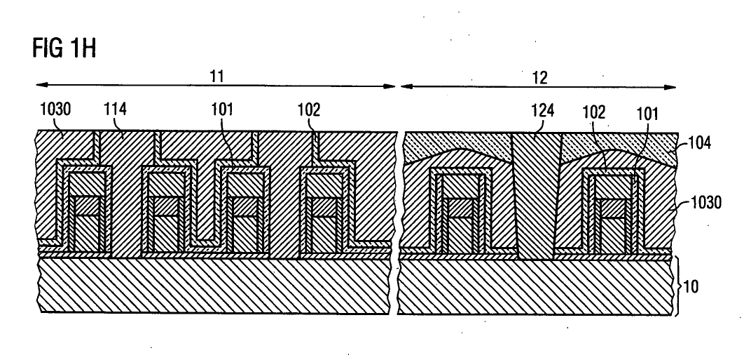

FIGS. 1A through 1H describe the fabrication method of an integrated memory device according a first embodiment of the present invention. The integrated memory device is formed in and on a semiconductor substrate 10, as shown in FIG. 1A. The semiconductor substrate 10 may already comprise memory cells, support electronic devices, and relating functionalized components. A memory cell—for example—usually comprises a capacitor and a selection transistor, both being formed within the semiconductor substrate 10. The integrated memory device further comprises at least two regions, an array region 11, and a support region 12. The memory cells are arranged predominantly in the array region 11, whereas support electronic devices are arranged in the support region 12. In both the array region 11 and in the support region 12 there are GC-lines 110 and 120, respectively.

A first dielectric layer 101 is provided on the semiconductor substrate 10 to cover the GC-lines 110 in the array region 11 and the sidewalls of GC-lines 120 in the support region 12, as shown in FIG. 1B. Further, bit line contacts dummies 111 are provided between two facing GC-lines 110 in the array region. In both the array region 11 and the support region 12 a second dielectric layer 102 is provided on the substrate, covering the GC-lines 110, 120, and the bit line contact dummies 111. The GC-lines 120 in the support region 12, including the second dielectric layer 102 have a height h₁ 191 above the semiconductor substrate 10. The bit line contact dummies 111 project above the GC-lines 110 in the array region 11 and have a height h₂ 192, which is higher than the height h₁ 191.

According to this embodiment of the present invention, a layer 103 of a material of a first isolation layer is deposited on the second dielectric layer 102, as shown in FIG. 1C. This material 103 is provided with a thickness being equal to or greater than half the spacing d 193 of two adjacent GC-lines 110 in the array region 11 in regions where there is no bit line contact dummy 111. Voids 112 may form in these interspaces of GC-lines 110, due to an excessive aspect ratio of the respective surface feature. Since this deposition applies to the entire integrated memory device, also the GC-lines 120 in the support region 12 are covered by the first isolation layer 103.

In a subsequent annealing step, the material 103 of the first isolation layer is annealed and molten to form a continuous and annealed first isolation layer 1030. The annealing is such that the voids 112 are filled by surrounding material 103 and the interspaces between facing GC-lines 110 in the array region are continuously filled and the surface is smoothened. Since feature density is lower in the support region 12, the effective maximum height hₘₐₓ 194 of the first isolation layer 1030 in the support region is reduced, compared to the respective height in the array region 11. According to this embodiment of the present invention, the height hₘₐₓ 194 is lower than the height h₂ 192. Hence, the bit line contact dummies 111 project above the GC-lines 120 in the array region 11 including the coverage by the second dielectric layer 102 and the first isolation layer 1030, as shown in FIG. 1D.

In a next step, as shown in FIG. 1E, a second isolation layer 104 is provided on the first isolation layer 1030. The second isolation layer 104 has a minimum height hₘᵢₙ 195 in the support region 12, being measured above the top surface of the semiconductor substrate 10, and being higher than the height h₂ 192 of the bit line contact dummies 111.

In a subsequent step polishing of the integrated memory device is performed such that the first isolation layer 1030 and the second isolation layer 104 are removed to expose the bit line contact dummies 111, as shown in FIG. 1F. Since polishing is carried out applying to the entire integrated memory device, also the second isolation layer 104 is polished in the support region 12.

Since the bit line contact dummies 111, having the height h₂ 192, are projecting above the GC-lines 120 in the support region 12 including the second dielectric layer 102 and the first isolation layer 1030, the bit line contact dummies 111 may be exposed by means of polishing, while the GC-lines 120 in the support region 12 are still covered by both the first isolation layer 1030 and the second isolation layer 104. Polishing in the support region 12 may be stopped in the top second isolation layer 104 and does not open the underlying first isolation layer 1030. Polishing hence occurs in a homogenous material with a locally homogenous abrasion rate and dishing is avoided or at least reduced in the support region 12. The inventive method, therefore, provides an interstitial planar surface of the integrated memory device, advantageously allowing for subsequent process stages of fabrication that require a smooth device surface in the support region 12.

In subsequent process stages, as shown in FIG. 1G and 1H, the bit line contact dummies 111, the first dielectric layer 101, and parts of the top surface of the semiconductor substrate 10 are removed to form holes 113. Furthermore, support contact holes 123 are formed by etching the first isolation layer 1030 and the second isolation layer 104 in the support region 12. Said holes 113 and 123 being simultaneously or subsequently filled by a conductive material to form bit line contacts 114 in the array region 11 and support contacts 124 in the support region 12. Both contacts 114 and 124 reach down to the semiconductor substrate 10 and establish electric contact to electronic entities within the semiconductor substrate 10, such as memory cells in the array region 11 or support electronic devices in the support region 12.

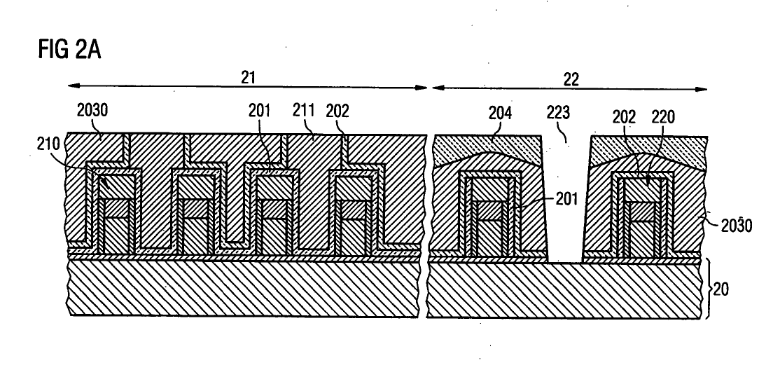

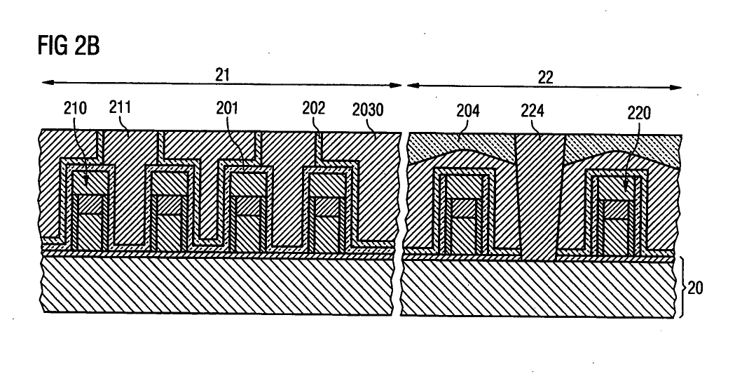

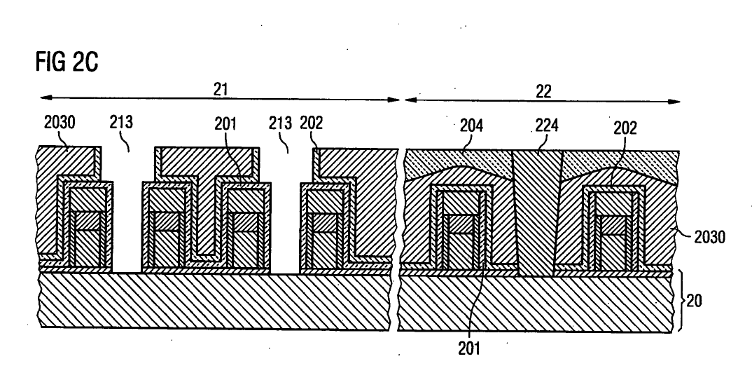

FIGS. 2A through 2C show an integrated memory device during a similar manufacturing process, as described in conjunction with FIGS. 1. According to this second embodiment of the present invention, similar features have been manufactured on top of a semiconductor substrate 20. As shown in FIG. 2A, the integrated memory device in this stage of fabrication comprises GC-lines 210 beneath a first dielectric layer 201, a second dielectric layer 202, a first isolation layer 2030, and a second isolation layer 204, and bit line contact dummies 211 in the array region 21 of the integrated memory device. Further, GC-lines 220 are arranged in a support region 22, these GC-lines 220 being covered by the second dielectric layer 202, the first isolation layer 2030, and the second isolation layer 204.

According to this embodiment of the present invention, holes 223 are formed down to the semiconductor substrate 20 between GC-lines 220 in the support region 22. The bit line contact dummies 211 remain unchanged during and after this process stage. Subsequently the holes 223 are filled by conductive material to form support contacts 224 in the support region 22, as shown in FIG. 2B.

In a subsequent process step, as shown in FIG. 2C, the bit line contact dummies 211 are removed to form holes 213 between the GC-lines 210 in the array region 21. During subsequent fabrication, these holes 213 may be filled by another conductive material to form bit line contacts, corresponding to the bit line contacts 114 in FIG. 1H. It is noted, that the removal of the bit line contact dummies 211 may also take place prior to the formation of the holes 223 in the support region 22.

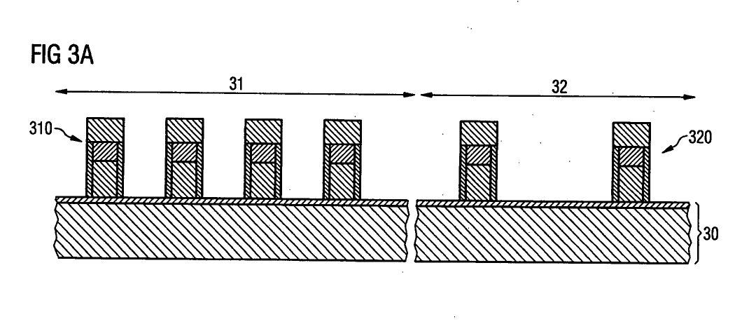

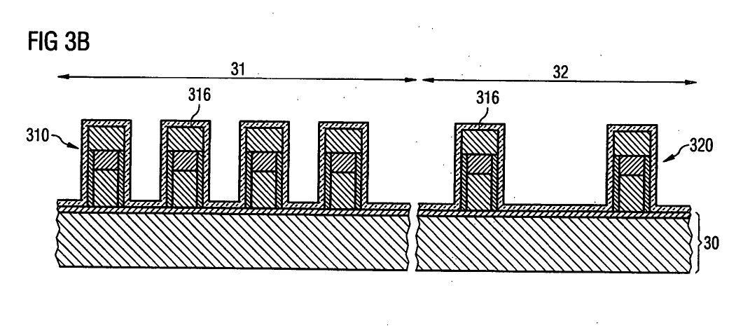

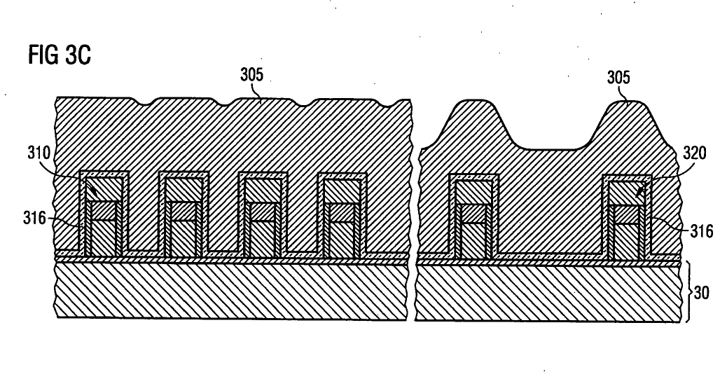

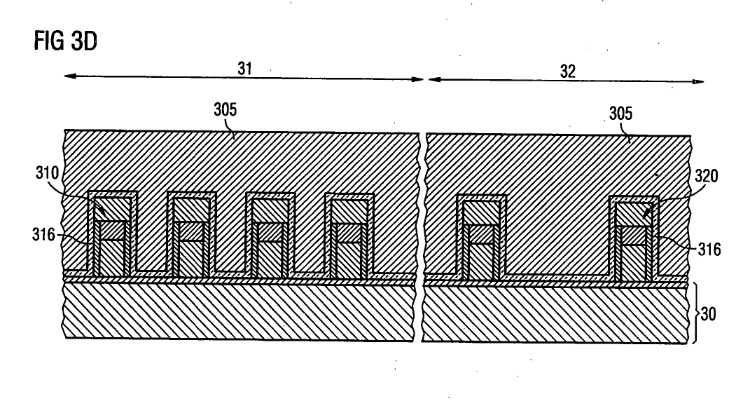

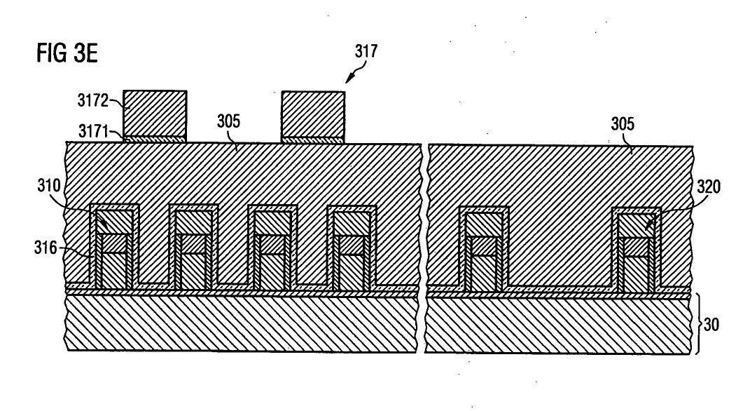

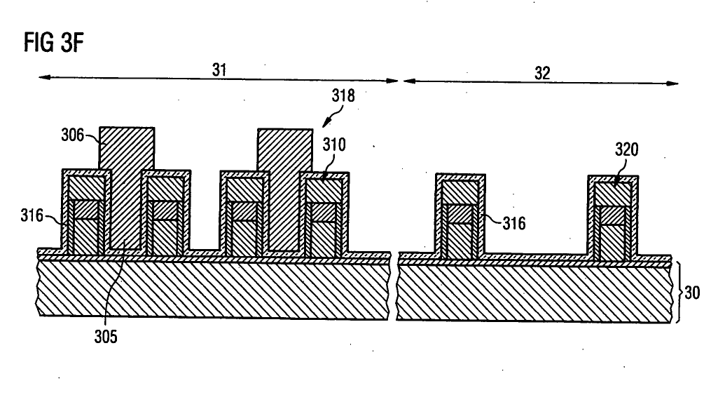

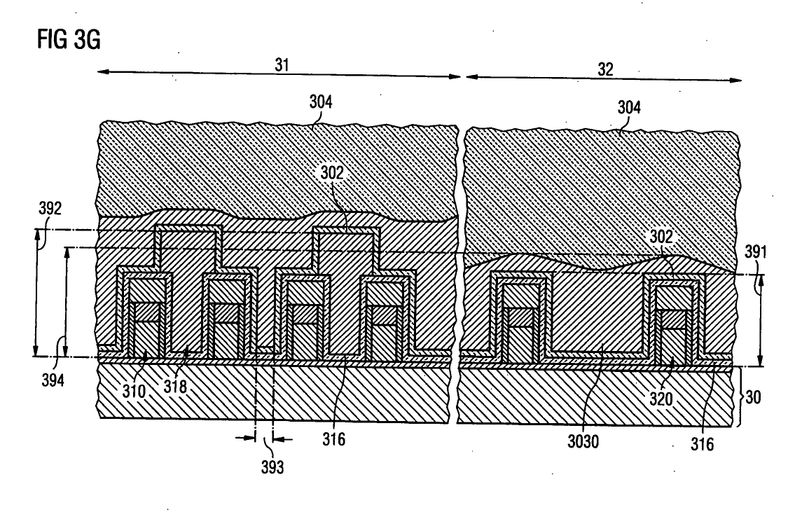

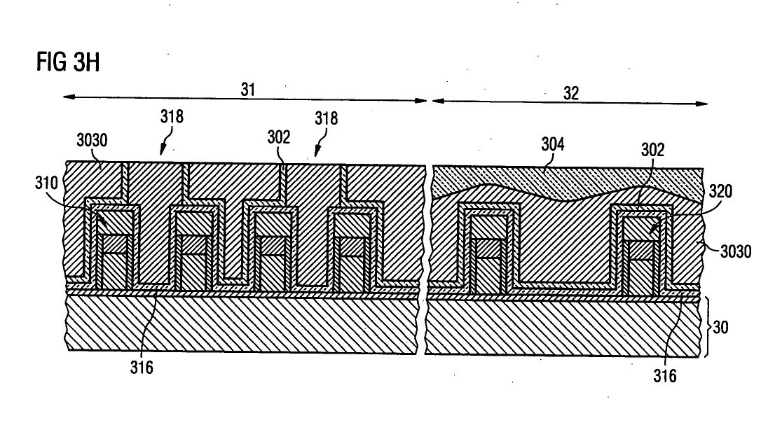

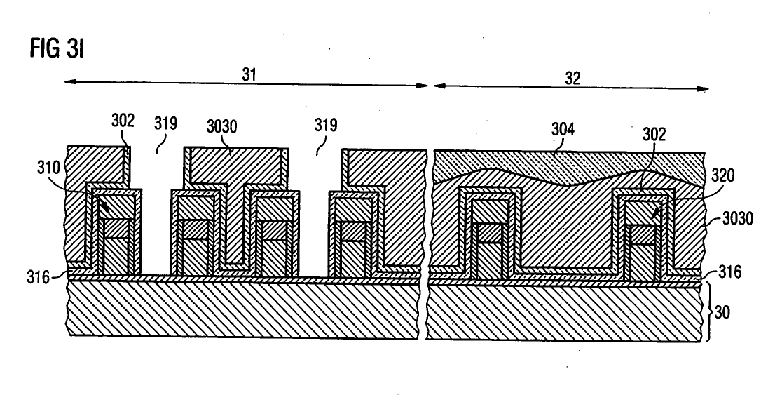

FIGS. 3A through 3K show an integrated memory device during fabrication in various process stages, according to a third embodiment of the present invention.

As shown in FIG. 3A, GC-lines 310 are arranged in an array region 31 of a semiconductor substrate 30. Further, GC-lines 320 are arranged in a support region 32 of the semiconductor substrate 30. The semiconductor substrate 30 comprises already functionalized elements, such as memory cells in the array region 31 and support electronic devices in the support region 32.

Electrical contacting of these electronic entities is mainly established via contacts being arranged on a top surface of the semiconductor substrate 30, such as the GC-lines 310, 320. The GC-lines 310, 320 may be composed of several materials, usually including poly-crystalline silicon, silicides, metals, or tungsten in a layered setup. Further, they may comprise isolating elements at their bottom or very top or at their sides, usually including dielectrics such as silica and/or silicon nitride.

In a subsequent step, as shown in FIG. 3B, a first dielectric layer 316 is provided on the semiconductor substrate 30, covering the GC-lines 310, 320. Preferably this first dielectric layer 316 comprises silicon-nitride (Si₃N₄) which is provided by means of established and reproducible processing techniques.

In a subsequent step, as shown in FIG. 3C, a sacrificial layer 305 is deposited on the semiconductor substrate 30, covering the GC-lines 310, 320 including the first dielectric layer 316. Said sacrificial layer 305 may comprise silicon, preferably in a poly-crystalline state. This poly-silicon may be easily provided and deposited, while there are established and well understood selective etching techniques—possessing a sufficiently high selectivity—for a later selective removal of the sacrificial layer 305 and other components of sacrificial material. A planar surface of the integrated memory device in this stage of fabrication is obtained, e. g. by means of a blind polish step, as shown in FIG. 3D.

By means of a subsequent lithographic process, as shown in FIG. 3E, material plugs 317 are formed on top of the sacrificial layer 305. Said material plugs 317 may comprise an anti reflection coating (ARC) 3171 and further material 3172. The material plugs 317 are arranged above the interspaces between two facing GC-lines 310 in the array region. The material plugs 317 are also covering parts of said GC-lines 310 and serve as an etching mask for a subsequent anisotropic etching step. Anisotropic etching removes the sacrificial layer 305 on the semiconductor substrate 30, except in the regions underneath the material plugs 317. Subsequently the material plugs 317, which may comprise the anti-reflection coating 3171 and the further material 3172, are removed, and remainders of the sacrificial layer 305 remain to form bit line contact dummies 318, as shown in FIG. 3F.

As shown in FIG. 3G, a second dielectric layer 302 is provided on the semiconductor substrate 30 in both the array region 31 and the support region 32, covering the GC-lines 310, 320, the bit line contact dummies 318, and the first dielectric layer 316. Preferably, the second dielectric layer 302 comprises silicon nitride.

A first isolation layer 3030 is provided on the second dielectric layer 302, by means of a combination of deposition and annealing techniques. Furthermore, the first isolation layer 3030 is provided such that its maximum height 394 above the GC-lines 320 in the support region 32 is lower than the height 392 of the bit line contact dummies 318 in the array region 31. The first isolation layer 3030 comprises preferably boron-phosphate-silicate-glass (BPSG). The BPSG preferably contains up to 6% of boron and 2% to 6% of phosphorous, whereas phosphate-silicate-glass (PSG) usually denotes the material with a vanishing boron concentration. Said annealing of the BPSG may advantageously remove voids, which may have been formed during deposition, and provide a continuous first isolation layer 3030 on top of the semiconductor substrate 30 and the reflow further provides a first planarization of the glass. The deposited thickness of the material of the first isolation layer 3030 is preferably equal to or greater than the half of the spacing 393 between two adjacent GC-lines 310 in the array region 31 where there is no bit line contact dummy 318. Said thickness is preferably in the range of 80 to 180 nm.

A second isolation layer 304 is provided subsequently on the first isolation layer 3030. The second isolation layer 304 may comprise silica, preferably, undoped silica glass which may be provided by means of chemical vapor deposition (CVD). During said CVD the reactants may comprise tetraethoxysilane (TEOS) and ozone (03), preferably with an ozone concentration ranging from 15% to 20%. Most preferably, the second isolation layer 304 is provided by means of plasma enhanced chemical vapor deposition (PE-CVD), the reactants of which may again comprise TEOS. Preferably, the second isolation layer 304 is provided such that the GC-lines 320 in the support region 32 including the first and the second dielectric layer 316, 302, having a height 391, are covered by the second isolation layer 304 up to the height 392 of the bit line contact dummies 318 in the array region 31, thus having a thickness which, preferably, ranges from 300 nm to 1000 nm.

In a subsequent polishing step, as shown in FIG. 3H, the integrated memory device is polished such that the bit line contact dummies 318 are exposed. The inventive method provides a reliable exposure of the dummies 318, while leaving the GC-lines 320 in the support region 32 still being covered by both the first isolation layer 3030 and the second isolation layer 304. In this way, the dummies 318 may be exposed and dishing is avoided, or, at least reduced, in the support region 32.

As shown in FIG. 3I, further process stages may apply to the integrated memory device, such as a removal of the bit line contact dummies 318 to provide holes 319, which may be subsequently filled by a conductive material to form the eventual bit line contacts. Furthermore, subsequent etching stages may be conducted to form holes in the support region, which may be also filled by conductive material to form support contacts. The order of the formation of said contacts may be reversed, or may occur also simultaneously, by filling the holes 319 in the array region 31 and etched regions in the support region 32 by means of one filling stage. Said conductive material may comprise a metal, poly-silicon, tungsten, or other related conductive materials or coumpounds thereof. Furthermore, a liner layer may be provided prior to the filling of the holes 319 for blocking unwanted diffusion of conductive material into functionalized areas of the semiconductor substrate 30.

The preceding description only describes advantageous exemplary embodiments of the invention. The features disclosed therein and the claims and the drawings can, therefore, be essential for the realization of the invention in its various embodiments, both individually and in any combination.

What is claimed is

1. Method of fabricating an integrated memory device including the steps of:
providing a semiconductor substrate, including an array region with memory cells and a support region with support electronic devices, said support region being arranged alongside said array region;
providing on said semiconductor substrate GC-lines of said memory cells in said array region and on said semiconductor substrate GC-lines of said support electronic devices in said support region, said GClines in said support region having a first height;
providing on said semiconductor substrate in the array region bit line contacts of said memory cells, said bit line contacts projecting above said GC-lines in said array region and in said support region, said bit line contacts having a second height, said second height being higher than said first height;
providing a first isolation layer on the semiconductor substrate, said first isolation layer covering said GC-lines and said bit line contacts, the maximum height of said GC-lines in the support region including the coverage of said first isolation layer being lower than said second height;
providing a second isolation layer on said first isolation layer; and
polishing said second isolation layer and said first isolation layer, such that a planar surface of the integrated memory device is provided and such that said bit line contacts are exposed.

2. Method as claimed in claim 1, wherein said first isolation layer and said second isolation layer are polished such that said GC-lines in said support region remain covered by said first isolation layer and said second isolation layer.

3. Method as claimed in claim 1, wherein said first isolation layer and said second isolation layer are polished by means of chemical-mechanical-polishing.

4. Method as claimed in claim 1, wherein the step of providing said first isolation layer comprises the steps of:
depositing a material of said first isolation layer; and
annealing said material of said first isolation layer.

5. Method as claimed in claim 4, wherein said material of said first isolation layer comprises phosphate-silicate-glass.

6. Method as claimed in claim 4, wherein said material of said first isolation layer comprises boron-phosphate-silicate-glass.

7. Method as claimed in claim 6, wherein the boron concentration of said boron-phosphate-silicate-glass ranges up to 6%.

8. Method as claimed in claim 6, wherein the phosphorus concentration of said boron-phosphate-silicate-glass ranges from 2% to 6%.

9. Method as claimed in claim 4, wherein said material of said first isolation layer is deposited with a first layer thickness, said first layer thickness being equal to or greater than half the spacing of said GC-lines in said array region, said spacing being measured parallel to the top surface of said semiconductor substrate.

10. Method as claimed in claim 9, wherein said first layer thickness ranges from 80 nm to 180 nm.

11. Method as claimed in claim 4, wherein said material of said first isolation layer is annealed such to remove voids in said material.

12. Method as claimed in claim 4, wherein said material of said first isolation layer is annealed such to reflow said first isolation layer and such to provide a smoothening of a surface of said first isolation layer.

13. Method as claimed in claim 4, wherein said material of said first isolation layer is annealed such to provide a void-free deposition of said second isolation layer.

14. Method as claimed in claim 1, wherein said second isolation layer comprises silica.

15. Method as claimed in claim 1, wherein said second isolation layer comprises undoped silica glass.

16. Method as claimed in claim 1, wherein said second isolation layer is provided by means of chemical vapor deposition.

17. Method as claimed in claim 16, wherein reactants during said chemical vapor deposition comprise tetraethoxysilane and ozone.

18. Method as claimed in claim 17, wherein the ozone concentration ranges from 15 to 20 per cent.

19. Method as claimed in claim 1, wherein said second isolation layer is provided by means of plasma enhanced chemical vapor deposition.

20. Method as claimed in claim 19, wherein reactants during the plasma enhanced chemical vapor deposition comprise tetra-ethoxysilane.

21. Method as claimed in claim 1, wherein said second isolation layer is provided with a second layer thickness, such that a minimum height of said GC-lines in said support region including the coverage of said first isolation layer and the coverage of said second isolation layer is equal to or greater than said second height.

22. Method as claimed in claim 21, wherein said second layer thickness ranges from 300 nm to 1000 nm.

23. Method of fabricating an integrated memory device including the steps of:
providing a semiconductor substrate, including an array region with memory cells and a support region with support electronic devices, said support region being arranged alongside said array region;
providing on said semiconductor substrate GC-lines of said memory cells in said array region and on said semiconductor substrate GC-lines of said support electronic devices in said support region;
providing on said semiconductor substrate in said array region and in said support region a first dielectric layer covering said GC-lines, said GC-lines in said support region including a coverage of said first dielectric layer having a GC-line height;
providing a sacrificial layer on said semiconductor substrate in said array region and in said support region, said sacrificial layer covering said GC-lines and said first dielectric layer and having a minimum height in regions between GC-lines in the array region, said minimum height being higher than said GC-line height;
providing material plugs on said sacrificial layer in said regions between the GC-lines in the array region;
anisotropic etching said sacrificial layer, said material plugs and the sacrificial layer underneath said material plugs remaining;
removing said material plugs;
providing a second dielectric layer on said semiconductor substrate, said second dielectric layer covering remainders of said sacrificial layer and said GC-lines;
providing a first-isolation layer on said second dielectric layer, the maximum height of said GC-lines in the support region including the coverage of said first dielectric layer, said second dielectric layer, and said first isolation layer being lower than the height of said remainders of the sacrificial layer;
providing a second isolation layer on said first isolation layer;
polishing said second isolation layer and said first isolation layer, such that a planar surface of the integrated memory device is provided and such that said remainders of the sacrificial layer are exposed;
removing said remainders of the sacrificial layer and said dielectric layer underneath the remainders of the sacrificial layer, leaving holes in said first isolation layer; and
providing bit line contacts by means of filling said holes with a conductive material.

24. Method as claimed in claim 23, wherein said first isolation layer and said second isolation layer are polished such that said GC-lines in said support region remain covered by said first isolation layer and said second isolation layer.

25. Method as claimed in claim 23, wherein said first isolation layer and said second isolation layer are polished by means of chemical-mechanical-polishing.

26. Method as claimed in claim 23, wherein the step of providing said first isolation layer comprises the steps of:
depositing a material of said first isolation layer; and
annealing said material of said first isolation layer.

27. Method as claimed in claim 26, wherein said material of said first isolation layer comprises phosphate-silicate-glass.

28. Method as claimed in claim 26, wherein said material of said first isolation layer comprises boron-phosphate-silicate-glass.

29. Method as claimed in claim 28, wherein the boron concentration of said boron-phosphate-silicate-glass ranges up to 6%.

30. Method as claimed in claim 28, wherein the phosphorus concentration of said boron-phosphate-silicate-glass ranges from 2% to 6%.

31. Method as claimed in claim 26, wherein said material of said first isolation layer is deposited with a first layer thickness, said first layer thickness being equal to or greater than half the spacing of said GC-lines in said array region including said first dielectric layer and said second dielectric layer, said spacing being measured parallel to the top surface of said semiconductor substrate.

32. Method as claimed in claim 31, wherein said first layer thickness ranges from 80 nm to 180 nm.

33. Method as claimed in claim 26, wherein said material of said first isolation layer is annealed such to remove voids in said material.

34. Method as claimed in claim 26, wherein said material of said first isolation layer is annealed such to reflow said first isolation layer and such to provide a smoothening of a surface of said first isolation layer.

35. Method as claimed in claim 26, wherein said material of said first isolation layer is annealed such to provide a void-free deposition of said second isolation layer.

36. Method as claimed in claim 23, wherein said second isolation layer comprises silica.

37. Method as claimed in claim 23, wherein said second isolation layer comprises undoped silica glass.

38. Method as claimed in claim 23, wherein said second isolation layer is provided by means of chemical vapor deposition.

39. Method as claimed in claim 38, wherein reactants during said chemical vapor deposition comprise tetraethoxysilane and ozone.

40. Method as claimed in claim 39, wherein the ozone concentration ranges from 15 to 20 per cent.

41. Method as claimed in claim 23, wherein said second isolation layer is provided by means of plasma enhanced chemical vapor deposition.

42. Method as claimed in claim 41, wherein reactants during the plasma enhanced chemical vapor deposition comprise tetra-ethoxysilane.

43. Method as claimed in claim 23, wherein said second isolation layer is provided with a second layer thickness, such that a minimum height of said GC-lines in said support region including the coverage of said first isolation layer and the coverage of said second isolation layer is equal to or greater than the height of said remainders of the sacrificial layer in the regions between said GC-lines in said array region.

44. Method as claimed in claim 43, wherein said second layer thickness ranges from 300 nm to 1000 nm.

45. Method as claimed in claim 23, wherein said first dielectric layer comprises silica.

46. Method as claimed in claim 23, wherein said second dielectric layer comprises silicon-nitride.

47. Method as claimed in claim 23, wherein said sacrificial layer comprises silicon.

48. Method as claimed in claim 47, wherein said silicon is in a poly-crystalline state.

49. Method as claimed in claim 23, wherein said conductive material comprises a metal.

50. Method as claimed in claim 23, wherein said conductive material comprises tungsten.

51. Method as claimed in claim 23, wherein said conductive material comprises a liner layer on a sidewall of said holes.
